(19) United States
(12) Patent Application Publication
(10) Pub. No.: US 2009/0009974 A1
(43) Pub. Date: Jan. 8, 2009

(54) DISPLAY DEVICE

(75) Inventors: Li-Wei TSENG, Taipei (TW); Chich-Hua Shen, Taipei (TW)

Correspondence Address: Muncy, Geissler, Olds & Lowe, PLLC, P.O. BOX 1364, FAIRFAX, VA, 22038-1364, US

(73) Assignee: AMA PRECISION INC.

(21) Appl. No.: 12/164,830

(22) Filed: Jun. 30, 2008

(30) Foreign Application Priority Data
Jul. 3, 2007 (TW) 96124193

(51) Int. Cl. H05K 7/20

(52) U.S. Cl. 361/711

(57) ABSTRACT

A display device includes a display panel, a back light module, a heat dissipation plate and a heat pipe. The display panel has a display surface. The back light module is coupled to the display panel, and this back light module includes a control circuit board. The heat dissipation plate contacts the control circuit board. The heat pipe contacts the heat dissipation plate. The length direction of the heat pipe is not parallel with a horizontal direction, and it is also not perpendicular to the display surface.

### RELATED APPLICATIONS

This application claims priority to Taiwan Application Serial Number 96124193, filed Jul. 3, 2007, which is herein incorporated by reference.

### BACKGROUND OF THE INVENTION

1. Field of the Invention

The invention relates to a heat dissipation device and, more particularly, to a heat dissipation device in an electronic device.

2. Description of the Related Art

With the progress of the science and technology and the rapid development of the media, users demand more and more for the peripheral acousto-optical device. The display utilizing cathode ray tubes (CRTs) or called iconoscopes is commonly used in the past. However, it does not meet the demand of lightness, slimness, shortness and smallness nowadays because of the overlarge size. Therefore, in recent years, many flat panel display technologies such as the liquid crystal display (LCD) are developed and become the main stream in the future gradually.

The LCD technology is developed rapidly and becomes mature day by day, and the power consumption of a LCD is low. Compared with a CRT used in a same size, the LCD occupies less room and has a less weight. Therefore, the LCD meets the demand of lightness, slimness, shortness and smallness completely, and it is widely used in various electronic products.

The liquid crystal television with a large size is developed rapidly. The size of a liquid crystal television with a large size is larger than that of a conventional plasma television with a large size. This kind of LCD mostly is back light LCD mainly including LCD panel at the front end and the back light module at the back end. Therefore, a large back light module should be used to provide a back light source with enough brightness. The light passes through the liquid crystal layer and arrives at the eyes of a user. However, along with the increase of the size of the back light module, dissipating heat for the back light module effectively becomes more difficult.

### BRIEF SUMMARY OF THE INVENTION

The invention provides a display device with heat pipes evening the inner heat.

According to an embodiment of the invention, a display device includes a display panel, a back light module, a heat dissipation plate and a heat pipe. The display panel has a display surface. The back light module is coupled to the display panel, and it includes a control circuit board. The heat dissipation plate contacts the control circuit board. The heat pipe contacts the heat dissipation plate. The length direction of the heat pipe is not parallel to the horizontal direction and is not perpendicular to the display surface of the display panel.

The display device of the invention further may include a radiating fin installed on at least one partial area of the heat dissipation plate. The heat pipe is held between the heat dissipation plate and the radiating fin.

To sum up, the display device of the invention can dissipate the heat for the control circuit board effectively and avoid the problem that the heat focus on the partial area and damages the control circuit board.

These and other features, aspects, and advantages of the present invention will become better understood with regard to the following description, appended claims, and accompanying drawings.

### BRIEF DESCRIPTION OF THE DRAWINGS

FIG. 1 is an exploded diagram showing a display device according to an embodiment of the invention.

FIG. 2 is a combined diagram showing the display device shown in FIG. 1.

FIG. 3 is a partial section diagram showing the display device along the line segment A shown in FIG. 2.

### DETAILED DESCRIPTION OF THE EMBODIMENT

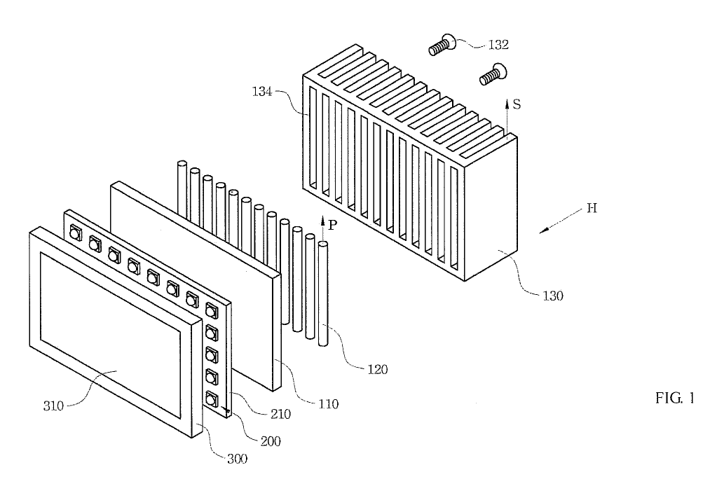

In the embodiment, the display device is, for example, a liquid crystal screen, a liquid crystal television or other display device with a back light module. Taking a display device (such as the display device shown in FIG. 1 to FIG. 3) with a back light module 200 using LEDs as its light source preferably as example, the embodiment of the invention is described.

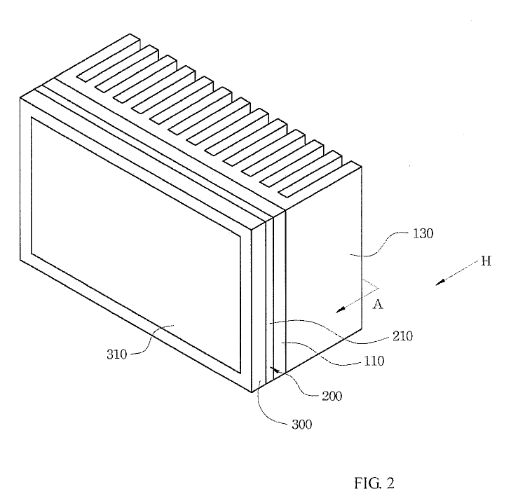

FIG. 1 and FIG. 2 are exploded diagram and combined diagram showing a display device according to one embodiment of the invention, respectively. A display device includes a display panel 300, a back light module 200, a heat dissipation plate 110 and a heat pipe 120. The display panel 300 has a display surface 310. The back light module 200 is coupled to the display panel 300, and it includes a control circuit board 210. The heat dissipation plate 110 contacts the control circuit board 210. The heat pipe 120 contacts the heat dissipation plate 110. The length direction P of the heat pipe 120 is not parallel to the horizontal direction H and is not perpendicular to the display surface 310 of the display panel 300. That is, the length direction of the heat pipe 120 is parallel to the gravity direction, or an included angle between zero degrees and ninety degrees is between the length direction of the heat pipe 120 and the gravity direction. In detail, the back light module 200 may be a back light module with LCDs as its light source, and the material of the heat dissipation plate 110 may include any kinds of metal or other material with a high heat conductivity (such as graphite and diamond).

The heat pipe 120 extends from the upper half of the heat dissipation plate 110 to the lower half of the heat dissipation plate 110 to even the heat of the upper half of the heat dissipation plate 110 and heat of the lower half of the heat dissipation plate 110. If the heat dissipation device does not have a fan and only has natural convection, the heat generated by the control circuit board 210 is focused at the upper half. Then, the performance of the components at the upper half of the control circuit board 210 decreases because of the over-high heat, and they even may be damaged. Therefore, if the heat pipe 120 extends from the upper half of the heat dissipation plate 110 to the lower half of the heat dissipation plate 110, the heat is conducted from the upper half to lower half effectively, and the partial area of the control circuit board 210 can avoid being damaged because of the over-high temperature.

In the embodiment, the included angle between the length direction of the heat pipe 120 and the horizontal direction H is between zero degrees and ninety degrees. In detail, the length direction of the heat pipe 120 shown in FIG. 1 may be perpendicular to the horizontal direction H, or the length direction of the heat pipe 120 may be parallel to the display surface 310 of the display panel 300. People having ordinary skills should know that the “included angle” means the least angle among four included angles formed by two intersecting directions. In addition, “the length direction of the heat pipe” means the extending direction such as the direction P shown in FIG. 1 of the heat pipe.

In addition, the display device shown in FIG. 1 also can have a radiating fin 130 installed on a partial area of the heat dissipation plate 110. The heat pipe 120 is held between the heat dissipation plate 110 and the radiating fin 130. In detail, the radiating fin 130 can be screwed on the partial area of the heat dissipation plate 100 by screws 132. Then, an assembler can adjust the position (or height) of the radiating fin 130 conveniently, and the heat focusing on the partial area of the heat dissipation plate 110 can be dissipated to the environment by the radiating fin 130.

The length direction of the radiating fin 130 may not be parallel to the horizontal direction H, or the length direction of the radiating fin may not be perpendicular to the display surface 310 of the display panel 300. Then, the radiating fin 130 extends from the upper half of the heat dissipation plate 110 to the lower half of the heat dissipation plate 110. In detail, the included angle between the length direction of the radiating fin 130 and the horizontal direction H is between the zero degrees and ninety degrees. In the embodiment, the length direction of the radiating fin 130 may be perpendicular to the horizontal direction H, or the length direction of the radiating fin 130 may be parallel to the display surface 310 of the display panel 300. People having ordinary skills should know that the “included angle” means the least angle among four included angles formed by two intersecting directions. In addition, “the length direction of the radiating fin” means the extending direction such as direction S shown in FIG. 1 of the radiating fin.

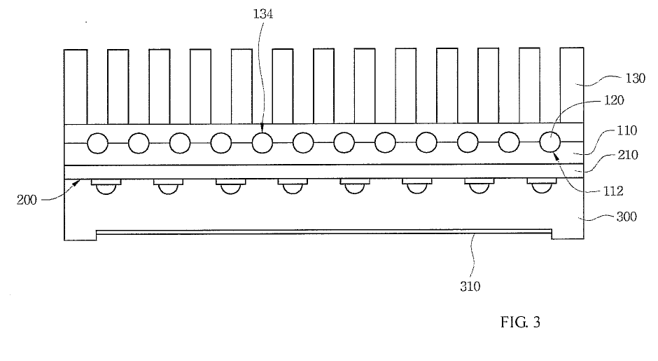

FIG. 3 is a partial section diagram showing the display device along the line segment A shown in FIG. 2. The radiating fin 130 of the embodiment has at least one recess 134 to allow part of the heat pipe 120 to be embedded into the recess 134. Then, the contact area between the heat pipe 120 and the radiating fin 130 increases, and then heat conducting ability between the heat pipe 120 and the radiating fin 130 is strengthened.

Similarly, the heat dissipation plate 110 shown in FIG. 3 also has at least one recess 112 to allow part of the heat pipe 120 to be embedded into the recess 112. The recess 112 also can increase the contact area between the heat pipe 120 and the heat dissipation plate 110, and then the heat conducting ability between the heat pipe 120 and the heat dissipation plate 110 is strengthened.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A display device comprising:
a display panel having a display surface;
a back light module coupled to the display panel and comprising a control circuit board;
a heat dissipation plate contacting the control circuit board; and
at least one heat pipe contacting the heat dissipation plate, wherein the length direction of the heat pipe is not parallel to a horizontal direction and is not perpendicular to the display surface.

2. The display device according to claim 1, wherein an included angle between zero degrees and ninety degrees is between the length direction of the heat pipe and the horizontal direction.

3. The display device according to claim 1, wherein the length direction of the heat pipe is parallel to the display surface.

4. The display device according to claim 1, wherein the length direction of the heat pipe is perpendicular to the horizontal direction.

5. The display device according to claim 1, further comprising at least one radiating fin installed on at least one partial area of the heat dissipation plate, wherein the heat pipe is held between the heat dissipation plate and the radiating fin.

6. The display device according to claim 5, wherein the length direction of the radiating fin is not perpendicular to the display surface.

7. The display device according to claim 5, wherein the length direction of the radiating fin is not parallel to the horizontal direction.

8. The display device according to claim 5, wherein an included angle between zero degrees and ninety degrees is between the length direction of the radiating fin and the horizontal direction.

9. The display device according to claim 5, wherein the length direction of the radiating fin is perpendicular to the horizontal direction.

10. The display device according to claim 5, wherein the length direction of the radiating fin is parallel to the display surface.

11. The display device according to claim 5, wherein the radiating fin is fixed on the partial area of the heat dissipation plate.

12. The display device according to claim 5, wherein the radiating fin has at least one recess, and at least part of the heat pipe is embedded into the recess.

13. The display device according to claim 1, wherein the heat dissipation plate has at least one recess, and at least part of the heat pipe is embedded into the recess.

14. The display device according to claim 1, wherein a light source of the back light module is a light emitting diode (LED).
